(19) United States
(12) Patent Application Publication
(10) Pub. No.: US 2002/0013053 A1
(43) Pub. Date: Jan. 31, 2002

(54) Method of producing a microwave device

(75) Inventors: Takashi Takagi, Omihachiman-shi (JP); Masaru Fujino, Otsu-shi (JP)

Correspondence Address: OSTROLENK FABER GERB & SOFFEN, 1180 AVENUE OF THE AMERICAS, NEW YORK, NY, 100368403

(73) Assignee: Murata Manufacturing Co., Ltd.

(21) Appl. No.: 09/906,540

(22) Filed: Jul. 16, 2001

(30) Foreign Application Priority Data
Jul. 21, 2000 (JP) 2000-221101

(51) Int. Cl. H01L 21/00; H01L 21/44

(52) U.S. Cl. 438/688

(57) ABSTRACT

A method of producing a microwave device using a magnetic garnet single crystal film involves cutting a garnet signal crystal substrate into chips. Thereafter, a magnetic garnet signal crystal film is grown on the surface of each of the garnet single crystal substrate chips by means of the liquid crystal epitaxial growth method. This method is advantageous in that no breakage of the single crystal substrate occurs during the growth of the magnetic garnet single crystal film, chipping does not occurs and a small variation in thickness of the film among substrates is achieved.

### BACKGROUND OF THE INVENTION

1. Field of the Invention

The present invention relates to a method of producing a microwave device using a magnetic garnet single crystal film produced by means of a liquid phase epitaxial growth method (hereinafter referred to as an LPE method).

2. Description of the Related Art

A magnetic garnet single crystal film is widely used as a material for various devices such as an optical isolator, a magnetostatic wave device and a microwave device. The magnetic garnet single crystal film for use such a device is generally grown by means of the LPE method.

That is, a source melt is produced by melting a solute for a component of a magnetic garnet single crystal film into a solvent. The source melt is placed in a noble metal crucible and a garnet single crystal substrate is brought into contact with the source melt in a state of supersaturation so as to grow a single crystal film on the surface of the substrate. A (111)-surface garnet single crystal substrate is used as the garnet single crystal substrate for the above purpose because the (111) surface of the garnet single crystal substrate has a high growth rate.

FIGS. 1-3 area schematic diagram illustrating a conventional method of producing a microwave device using a magnetic garnet single crystal film.

In this conventional method for producing a microwave device using a magnetic garnet single crystal film, first, as shown in the side view of FIG. 1, a garnet single crystal substrate 4 held by a substrate holder 3 is soaked in a source melt 2 in a crucible 1 so as to grow a magnetic garnet single crystal film by means of the LPE method. Thereafter, as shown in FIG. 2, the substrate 5 having the magnetic garnet single crystal film formed thereon is cut, for example, along lines represented by dashed lines in FIG. 2, into a plurality of magnetic garnet single crystal film chips 6. Thus, magnetic garnet single crystal film chips 6 having a desired size are obtained as shown in a plan view of FIG. 3. The obtained magnetic garnet single crystal film chips 6 can be used as microwave devices.

To meet a need for a reduction in the size of microwave devices, an improvement in productivity and reduction in production cost, efforts have been made in recent years to grow a magnetic garnet single crystal film on a garnet single crystal substrate with a greater size or to grow a magnetic garnet single crystal film on a plurality of single crystal substrates at the same time (as disclosed, for example, in Japanese Examined Patent Application Publication No. 7-48442).

However, when a magnetic garnet single crystal film is grown on a garnet single crystal substrate having a large size, a large stress occurs due to lattice mismatching between the single crystal substrate and the single crystal film grown on the surface of the substrate, and, sometimes, the large stress causes the single crystal substrate to be broken during the growth of the single crystal film. Another problem arising from use of a large sized substrate is that a large stress remains in the substrate after growing the magnetic garnet single crystal film on the substrate, and chipping (breakage at a cut face) often occurs when the substrate is cut into chips with a desired shape. The chipping results in a further reduction in the yield in production of microwave devices.

The above problems become more serious as the size of the microwave device is reduced. For example, after growing a Y₃Fe₅O₁₂ single crystal film (hereinafter referred to as a YIG single crystal film) with a thickness of 0.1 mm on the surface of a Gd₃Ga₅O₁₂ (hereinafter referred to as a GGG substrate) with a thickness of 0.5 mm, the substrate is cut into chips with a size of 0.5 mm cubic, the yield is lower than 68%.

In the case where a magnetic garnet single crystal film is grown on a plurality of garnet single crystal substrates at the same time, a problem is that there is a large variation in thickness of the single crystal films grown on the substrates.

In view of the above, it is an object of the present invention to provide a microwave device production method advantageous in that a magnetic garnet single crystal film can be grown without encountering breakage of a garnet single crystal substrate, the grown single crystal film has a less variation in thickness and chipping can be suppressed.

### SUMMARY OF THE INVENTION

According to an aspect of the present invention, there is provided a method of producing a microwave device using a magnetic garnet single crystal film grown by a liquid crystal epitaxial growth method comprising the steps of: cutting a garnet single crystal substrate into a plurality of garnet single crystal substrate chips; and growing a magnetic garnet signal crystal film on the surface of a plurality of the resulting garnet single crystal substrate chips by means of the liquid crystal epitaxial growth method. The plurality of chips which result from the cutting can be more than 500 or 1,000 or even more than about 10,000. The production of unusable chips due to chipping can be minimized by taking due care and usually at least about 85%, often at least about 90% or more, are suitable for the next step, namely being subjected to the liquid crystal epitaxial growth method.

Preferably, a (111)-surface garnet single crystal substrate is used as the garnet single crystal substrate in this microwave device production method and the garnet single crystal substrate is cut such that (110) surfaces appear as a pair of opposing cut surfaces and (211) surfaces appear as another pair of opposing cut surfaces.

Furthermore, the magnetic garnet single crystal film in this microwave device production method is preferably grown such that the plurality of garnet single crystal substrate chips are placed in a mesh-shaped container and the mesh-shaped container is soaked in a single crystal source melt while rotating the mesh-shaped container, thereby growing the magnetic garnet single crystal film on the surface of each garnet single crystal substrate chip.

Because a magnetic garnet single crystal film is grown on the surface of each garnet single crystal substrate chip after cutting the garnet single crystal substrate into chips in the microwave device production method according to the present invention, the stress due to lattice mismatching between the single crystal substrate and the grown single crystal film is reduced, and thus breakage of the single crystal substrate during the growth of the single crystal film is prevented. Furthermore, because the single crystal substrate is cut into chips before forming the single crystal film on the surface of the single crystal substrate, the problem of the stress remaining in the substrate after growing the single crystal film on the substrate can be eliminated, and thus chipping during the cutting process can be reduced.

In addition, because the garnet single crystal substrate is cut so that (110) and (211) surfaces, which have a lower growth rate than (111) surfaces, appear at cut faces, the crystal can be efficiently grown on (111) surfaces having a high growth rate.

Because garnet single crystal substrate chips are placed in a mesh-shaped container and the mesh-shaped container is soaked in a single crystal source melt while rotating the container thereby growing a magnetic garnet single crystal film on the surface of each single crystal substrate chip, it is possible to grow the magnetic garnet single crystal film on the surface of each of a large number of single crystal substrate chips at the same time in a highly reliable fashion.

### BRIEF DESCRIPTION OF THE DRAWINGS

FIGS. 1-3 are a schematic diagram illustrating a conventional method of producing a magnetic garnet single crystal film chip, wherein

FIG. 1 is a side view illustrating a garnet single crystal substrate held by a substrate holder and also illustrating a crucible including a source melt placed therein,

FIG. 2 is a plan view illustrating an obtained substrate having a magnetic garnet single crystal film formed thereon, and

FIG. 3 is a plan view illustrating magnetic garnet single crystal film chips obtained by cutting the substrate;

FIGS. 4-6 are a schematic diagram illustrating a method of producing a YIG single crystal film chip according to a first embodiment of the invention, wherein

FIG. 4 is a plan view of a GGG substrate,

FIG. 5 is a side view showing a mesh-shaped chip case held by a holder and also showing a crucible including a source melt placed therein, and

FIG. 6 is a plan view of obtained YIG single crystal film chips.

FIG. 7 is a cross-sectional view of a YIG signal crystal film chip cut along a (211) plane, produced according to the first embodiment of the invention;

FIG. 8 is a cross-sectional view of a YIG signal crystal film chip cut along a (110) plane, produced according to the first embodiment of the invention; and

FIGS. 9-11 are a schematic diagram illustrating a method of producing a YIG single crystal film chip according to a second embodiment of the invention, wherein

FIG. 9 is a plan view of a GGG substrate,

FIG. 10 is a side view showing two mesh-shaped chip cases vertically stacked and held by a holder, and also showing a crucible including a source melt placed therein, and

FIG. 11 is a plan view of obtained YIG single crystal film chips.

### DESCRIPTION OF THE PREFERRED EMBODIMENTS

The present invention is described in further detail below with reference to specific embodiments.

### FIRST EMBODIMENT

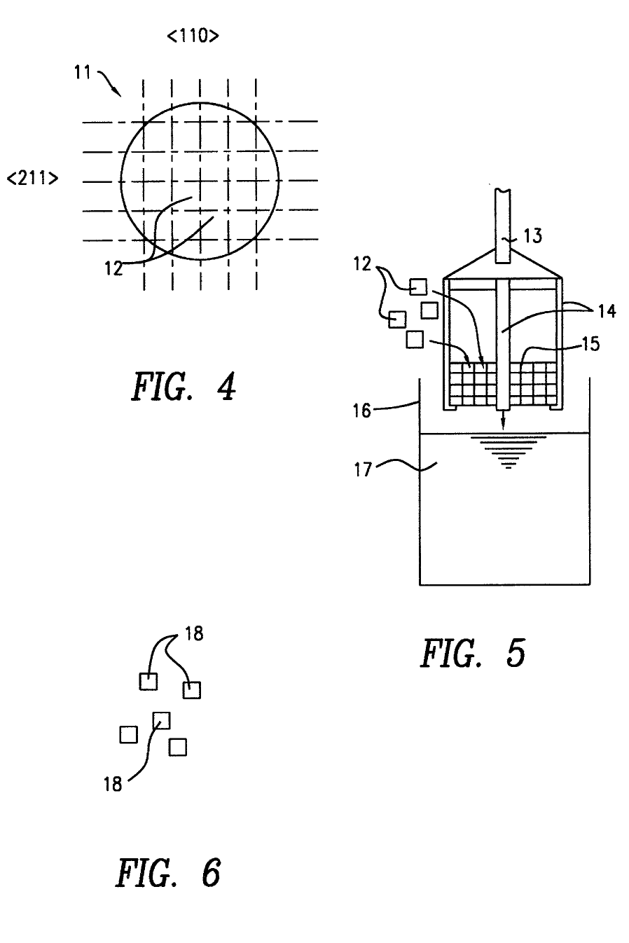

FIGS. 4-6 are a schematic diagram illustrating a method of producing a magnetic garnet single crystal film chip for use as a microwave isolator according to a first embodiment.

First, as shown in a plan view of FIG. 4, a circular-shaped (11 )-surface GGG substrate 11 with a thickness of for example 0.5 mm and a diameter of 76.2 mm was prepared.

The GGG substrate 11 was then cut at a speed of 2 mm/sec using a dicing saw such that (110) surfaces appeared at a pair of opposing cut faces and (211) surfaces appeared at another pair of opposing cut faces. As a result, 17,000 GGG substrate chips 12 with a size of 0.5 mm×0.5 mm×0.5 mm were obtained. Although chipping occurred during the above cutting process, a good yield of higher that 95% was obtained. Note that the dashed lines across the GGG substrate 11 simply indicate the directions of cutting, and the cutting width is not shown in the figure.

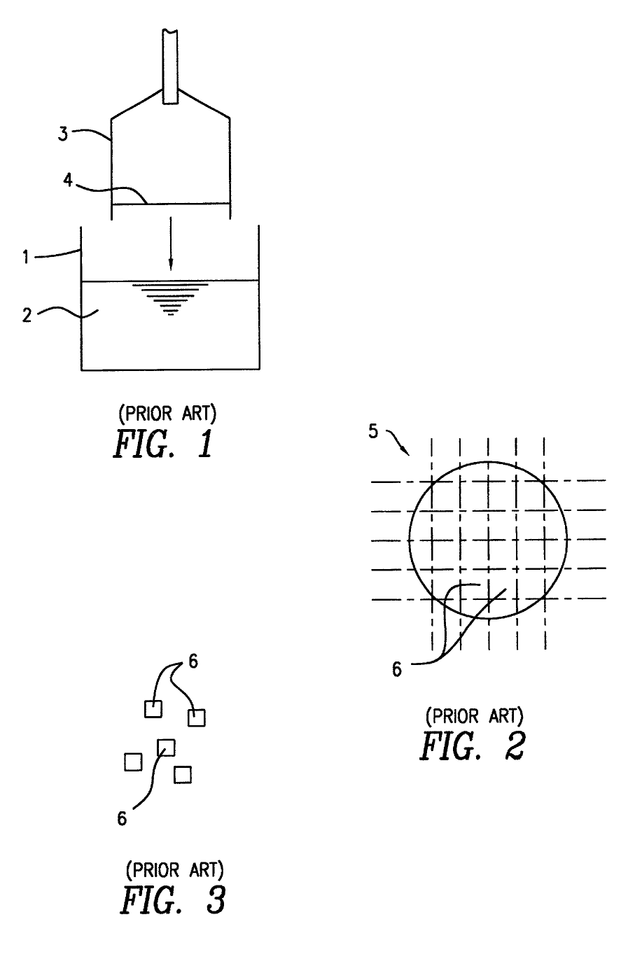

Thereafter, a mesh-shaped platinum chip case 15 such as that shown in FIG. 2 was prepared. The mesh-shaped platinum chip case 15 was held by a plurality of legs 14 of a holder 13 with a diameter of 80 mm connected to a rotation driver apparatus (not shown). The 17,000 GGG substrate chips 12 obtained in the above-described manner were placed in the mesh-shape platinum chip case 15.

The mesh-shaped platinum chip case 15 including the GGG substrate chips placed therein was soaked in a supersaturated source melt 17 in a crucible 16 for 6 hours while rotating the chip case 15 at 100 rpm, thereby growing a YIG single crystal film on the entire surface of each of the GGG substrate chips placed in the mesh-shaped platinum chip case 15. Thus, YIG single crystal film chips were obtained.

In the above process, the source melt 17 was produced by dissolving Y₂O₃ and Fe₂O₃, that is, components of YIG, into a solvent including PbO as a principal constituent. The amount of the source melt was about 10 kg. A platinum crucible with a diameter of 150 mm and a depth of 150 mm was used as the crucible 16.

After cooling the obtained YIG single crystal chips to room temperature, the chips were subjected to an acid treatment using HNO₃ so as to remove the source melt remaining on the chips. As a result, as shown in FIG. 3, YIG single crystal film chips 18 with a size of 0.8 mm×0.7 mm×0.6 mm were obtained.

The YIG single crystal film chips obtained via the above-described process were inspected, and no breakage was observed in any GGG substrate chip.

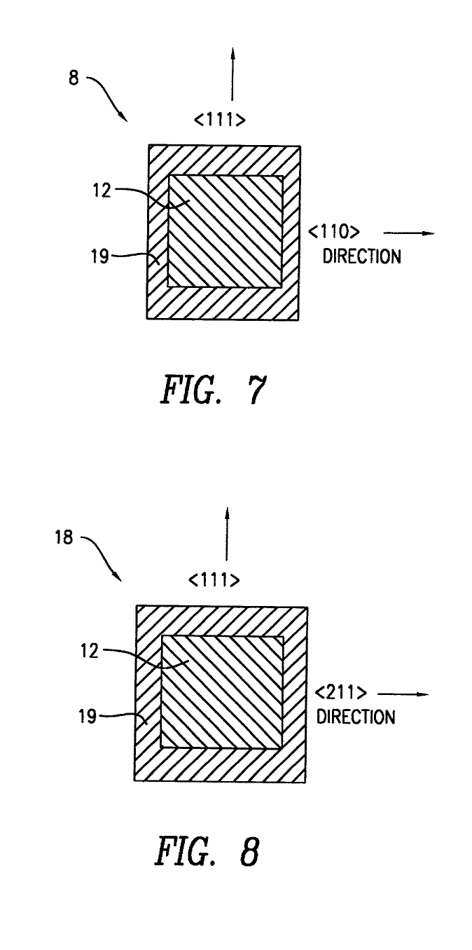

FIG. 7 is a cross-sectional view of a YIG single crystal film chip 18 of one of the obtained chips, taken along a (211) plane, and FIG. 8 is a cross-sectional view of another YIG single crystal film chip 18 of one of the chips, taken along a (211) plane. As can be seen from FIGS. 7 and 8, although the YIG single crystal film 19 has been grown over all surfaces of the GGG substrate chip 12, that is, in the respective <111>, <110>, and <211>directions, the YIG single crystal film has been grown to a greatest thickness in the <111>direction which is an easy growth axis.

Microwave isolators were produced using the YIG single crystal film chips obtained in the above-described manner. The overall yield in the production process starting from the cutting of the GGG substrate into chips was as high as 90% or higher.

Because the mesh-shaped chip case is rotated in the source melt, the GGG substrate chips are maintained in good contact with the source melt during the growth of the YIG single crystal film. The YIG single crystal film grown on the surface of each chip has a smaller specific gravity than Pb which is a constituent of the source melt. Therefore, the chips can easily move within the chip case. This prevents the chips from being overlapped with each other or being brought into complete contact with each other in the chip case and thus preventing a single crystal film from growing.

### SECOND EMBODIMENT

Two mesh-shaped platinum chip cases similar to that used in the first embodiment were placed in a vertically stacked fashion. GGG substrate chips were placed in the respective chip cases, and a magnetic garnet single crystal film was grown on each chip.

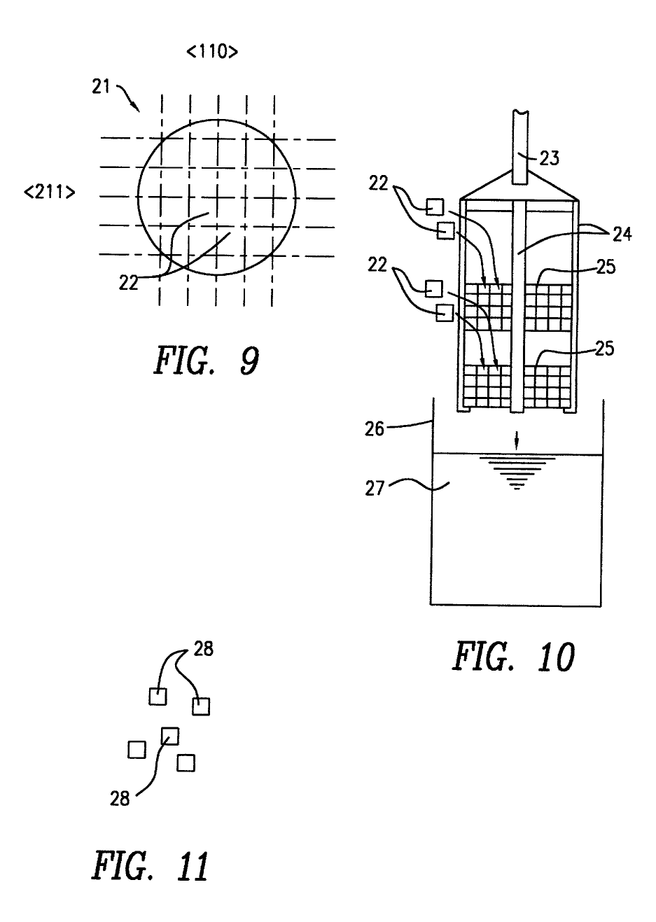

FIGS. 9-11 are a schematic diagram illustrating a method of producing a magnetic garnet single crystal film chip for use as a microwave isolator, according to a second embodiment of the present invention.

First, two (111)-surface GGG substrates with the same shape and the same size as those of the substrate used in the first embodiment were prepared. As shown in a plan view of FIG. 9, each GGG substrate 21 was cut in a similar manner to the first embodiment to obtain 34,000 GGG substrate chips 22 with the same size as that in the first embodiment. Although chipping occurred as in the first embodiment, a yield higher than 95% was obtained.

Note that the dashed lines across the GGG substrate 11 simply indicate the directions of cutting, and the cutting width is not shown in the figure.

Thereafter, two mesh-shaped platinum chip cases 25 with the same size as that used in the first embodiment were prepared as shown in FIG. 10. The two mesh-shaped platinum chip cases 25 were vertically stacked and held by a plurality of legs 24 of a holder 23 connected to a rotation driver apparatus. The substrate chips 22 obtained in the above-described manner were placed in the mesh-shape platinum chip cases 25 such that 17,000 chips were placed in each case.

The mesh-shaped platinum chip cases 25 including the GGG substrate chips placed therein were soaked in a supersaturated source melt 27 in a crucible 26 in a similar manner to the first embodiment thereby growing a YIG single crystal film on the entire surface of each of the GGG substrate chips. Thus, YIG single crystal film chips were obtained.

The composition and the amount of the source melt were the same as those in the first embodiment. The crucible with same size made of the same material as the crucible used in the first embodiment was used.

After the growth, source melt remaining on the chips was removed in a similar manner to the first embodiment. As a result, as shown in FIG. 11, YIG single crystal film chips 28 with the same size as in the first embodiment were obtained.

The YIG single crystal film chips obtained via the above-described process were inspected, and no breakage was observed in any GGG substrate chips, as in the case of the first embodiment.

Some of the YIG single crystal film chips were cut in a similar manner to the first embodiment, and the cut surfaces were observed. The observation has revealed that the YIG single crystal film has been grown on the surfaces of the GGG substrate in a similar manner to the first embodiment.

Although in the second embodiment, the YIG single crystal film was grown at the same time on twice the number of chips in the first embodiment, using the vertically-stacked two mesh-shaped platinum chip cases, the variation in thickness of the grown YIG single crystal film was as good as in the first embodiment.

Microwave isolators were produced using the YIG single crystal film chips obtained in the above-described manner. The overall yield in the production process was similar to that obtained in the first embodiment, that is, as high as 90% or higher.

As can be understood from the above description, the present invention provides great advantages. That is, no breakage of a garnet single crystal substrate occurs during the growth of a magnetic garnet single crystal film and chipping which occurs when the garnet single crystal substrate is cut is suppressed. As a result, microwave devices can be produced with a high yield. Because the variation in thickness of the magnetic garnet single crystal film is small enough even when the film is grown on a large number of chips, a large number of microwave devices can be produced in a highly reliable fashion.

What is claimed is:

1. A method of producing a microwave device using a magnetic garnet single crystal film by the liquid crystal epitaxial growth method, comprising:
cutting a garnet single crystal substrate into a plurality of garnet single crystal substrate chips; and
simultaneously growing a magnetic garnet single crystal film on the surface of a plurality of the resulting garnet single crystal substrate chips by the liquid crystal epitaxial growth method.

2. A method of producing a microwave device according to claim 1, wherein a (111)-surface garnet single crystal substrate is used as said garnet single crystal substrate, and said garnet single crystal substrate is cut such that (110) surfaces appear as a pair of opposing cut surfaces and (211) surfaces appear as another pair of opposing cut surfaces.

3. A method of producing a microwave device according to claim 2, wherein said plurality of garnet single crystal substrate chips are placed in a mesh-shaped container and said mesh-shaped container is soaked in a single crystal source melt while rotating said mesh-shaped container thereby growing a magnetic garnet single crystal film on the surface of each garnet single crystal substrate chip.

4. A method of producing a microwave device according to claim 3, wherein the substrate is cut into more than 500 chips.

5. A method of producing a microwave device according to claim 4, wherein the substrate is cut into more than 1,000 chips.

6. A method of producing a microwave device according to claim 5, wherein the substrate is cut into more than about 10,000 chips.

7. A method of producing a microwave device according to claim 1, wherein said plurality of garnet single crystal substrate chips are placed in a mesh-shaped container and said mesh-shaped container is soaked in a single crystal source melt while rotating said mesh-shaped container thereby growing a magnetic garnet single crystal film on the surface of each garnet single crystal substrate chip.

8. A method of producing a microwave device according to claim 7, wherein the substrate is cut into more than 500 chips.

9. A method of producing a microwave device according to claim 8, wherein the substrate is cut into more than 1,000 chips.

10. A method of producing a microwave device according to claim 9, wherein the substrate is cut into more than about 10,000 chips.

11. A method of producing a microwave device using a magnetic garnet single crystal film by the liquid crystal epitaxial growth method, comprising:
providing a plurality of garnet single crystal substrate chips, each of said chips having three pairs of opposing surfaces of which one pair are (111) surfaces, one pair are (110) surfaces and one pair are (211) surfaces; and
simultaneously growing a magnetic garnet single crystal film on the surface of the plurality garnet single crystal substrate chips by the liquid crystal epitaxial growth method.

12. A method of producing a microwave device according to claim 11, wherein said plurality of garnet single crystal substrate chips are placed in a mesh-shaped container and said mesh-shaped container is soaked in a single crystal source melt while rotating said mesh-shaped container thereby growing a magnetic garnet single crystal film on the surface of each garnet single crystal substrate chip.

13. A method of producing a microwave device according to claim 12, wherein the plurality is more than 500 chips.

14. A method of producing a microwave device according to claim 13, wherein the plurality is more than 1,000 chips.

15. A method of producing a microwave device according to claim 4, wherein the plurality is more than about 10,000 chips.
